(19) United States
(12) Patent Application Publication
(10) Pub. No.: US 2011/0117387 A1
(43) Pub. Date: May 19, 2011

(54) METHOD FOR PRODUCING METAL NANODOTS

(76) Inventors: Shivaraman Ramaswamy, Kancheepuram District (IN); Gopalakrishnan Chandasekaran, Kancheepuram District (IN)

(21) Appl. No.: 12/947,558

(22) Filed: Nov. 16, 2010

(30) Foreign Application Priority Data
Nov. 17, 2009 (IN) 2828/CHE/2009

(51) Int. Cl. G11B 5/84; B05D 5/02; C23C 14/34; C23C 14/14; C25D 5/02; C30B 23/02; G11B 5/62; G11B 5/85; G11B 5/851; G11B 5/855; G11B 5/858; B32B 3/26; B82Y 10/00

(52) U.S. Cl. 428/800; 427/282; 204/192.1; 427/597; 205/135; 427/600; 117/106; 428/320.2; 977/773

(57) ABSTRACT

A method for fabricating metal nanodots on a substrate is provided. The method includes: preparing a nanoporous polysulfone membrane; applying the nanoporous polysulfone membrane onto a substrate; depositing a metal into the pores of the polysulfone membrane thereby forming metal nanodots on the substrate; and removing the nanoporous polysulfone membrane.

### CROSS-REFERENCE TO RELATED APPLICATION

The present application claims priority to Indian Patent Application No. 2828/CHE/2009, filed with the Indian Patent Office on Nov. 17, 2009, the entire content of which is hereby incorporated by reference.

### FIELD OF THE DISCLOSURE

The present disclosure relates to a method for fabricating metal nanodots. In particular, the disclosure relates to a method for fabricating metal nanodots on a substrate using a nanoporous polysulfone membrane as a template. The present disclosure also relates to a system for fabricating metal nanodots.

### BACKGROUND

The fabrication of metal nanodots on a suitable substrate is a crucial progressive step towards nanoelectronic systems. Metal-silicon binary systems have received much attention over the past few decades due to multiple reasons. Studies have been conducted to understand the fundamentals of silicide formation as well as explore the applications of metal silicides in microelectronics technology. Metal silicides are now widely used in microelectronics for reliable contacts, interconnections, gates, Schottky barriers, etc., which have potential applications in next generation electronic devices (S. P. Murarka, Silicides for VLSI Applications, Academic Press, New York (1983); J. M. Poate, K. N. Tu and J. W. Mayer, Thin Films—Interdiffusion and Reaction, Wiley (1978); G. Ottaviani, J. Vac. Sci. Technol. 1, 1112 (1979)). Some metal silicides, such as nickel monosilicide, find applications in very large scale integration circuits while others such as nickel disilicide, find potential applications as metal-base transistors and buried epitaxial silicides (D. X. Xu, S. R. Das, C. J. Peters and L. E. Erickson, Thin Solid Films 326, 143 (1998); M. C. Poon et al., Appl. Surf. Sci. 157, 29 (2000); J. P. Gambino and E. G. Colgan, Mater. Chem. Phys. 52, 99 (1998); K. C. R. Chiu, J. M. Poate, L. C. Feldman and C. J. Doherty, Appl. Phys. Lett. 36, 544 (1980); L. J. Chen and J. W. Mayer, Thin Solid Films 93,135 (1982)).

Bit-patterned media have for long been explored for their potential in high density storage devices. Recently, bit-patterned media have been put forward as a solution to the trilemma problem, of satisfying the concurrent requirements of thermal stability, writability, and a high signal to noise ratio. In bit-patterned media, each nanostructured dot corresponds to one recorded bit, so that the magnetization reversal behavior of each dot directly governs the recording performance of the media. For this application, magnetic nanodots need to be fabricated. Several methods for fabricating such nanodots have been developed in the past. Various lithography techniques such as optical (D. Ali and H. Ahmed, Appl. Phys. Lett. 64, 2119 (1994)), electron beam (E. Leobanhung, L. Guo, Y. Wang, and S. Y. Chou, Appl. Phys. Lett. 67, 938 (1995); A. A. Tseng, K. Chen, C. D. Chen and K. J. Ma, IEEE Trans. Electron. Packag. Manuf. 26, 141 (2003)), reactive or focused ion beam (D. Ali and H. Ahmed, Appl. Phys. Lett. 64, 2119 (1994); E. Leobanhung, L. Guo, Y. Wang, and S. Y. Chou, Appl. Phys. Lett. 67, 938 (1995)), X-ray and scanning probe lithography (A. A. Tseng, K. Chen, C. D. Chen and K J. Ma, IEEE Trans. Electron. Packag. Manuf. 26, 141 (2003); T. Yasuda, S. Yamasaki and S. Gwo, Appl. Phys. Lett. 77, 3917 (2000); S. Anders et al., Microelectron. Eng. 61-62, 569 (2002)) have been developed to fabricate arrays of nanodots. However, these techniques are plagued by the high cost and lack of scalability. Recently, much attention has been focused towards preparing nanostructures using one or more polymer matrices as a template. For instance, U.S. Pat. No. 7,166,663 describes nanostructured compositions comprising a polymeric or oligomeric matrix material, a nano-sized particulate fraction and a micron-sized particulate fraction, the particles being either metal, metal oxides or combinations thereof U.S. Patent Application No. 2006/0124467 discloses a novel method for making nanopatterned templates which utilizes oriented degradable block copolymers and S. L. Cheng et al. (Journal of Physics and Chemistry of Solids 69 (2008), 620-624) describe the fabrication of 2-D periodic arrays of nickel metal dots using polystyrene (PS) nanosphere lithography. However, these polymers usually suffer from very low thermal stability and have much larger pore sizes thereby limiting the desired morphology of the nanostructured materials.

Therefore there exists a need for a low-cost, high-throughput technique, for the synthesis of metal nanodots. The present invention, which is a novel method of fabricating metal nanodots using nanoporous polysulfone membrane templates, provides a solution to the above mentioned problems.

### SUMMARY OF THE INVENTION

In one aspect, a method for fabricating metal nanodots on a substrate comprises: preparing a nanoporous polysulfone membrane; applying the nanoporous polysulfone membrane onto a substrate; depositing a metal into the pores of the polysulfone membrane thereby forming metal nanodots on the substrate; and removing the nanoporous polysulfone membrane.

In another aspect, a system for fabricating metal nanodots on a substrate comprises a nanoporous polysulfone membrane; a substrate; and a metal.

In yet another aspect, a magnetic data storage medium comprises metal nanodots. The metal nanodots are produced by the steps of: preparing a nanoporous polysulfone membrane; applying the nanoporous polysulfone membrane onto a substrate; depositing a metal into the pores of the polysulfone membrane thereby forming metal nanodots on the substrate; and removing the nanoporous polysulfone membrane.

### BRIEF DESCRIPTION OF THE DRAWINGS

The present invention is illustrated in the accompanying drawings:

FIG. 1 shows the Scanning Electron Microscopy image of a nanoporous polysulphone membrane synthesized using phase inversion polymerization;

FIG. 2 shows the Atomic Force Microscopy image of nickel nanodots fabricated using a polysulfone membrane;

FIG. 3 shows the 3D image of nickel nanodots;

FIG. 4 shows the Magnetic Force Microscopy images of nickel nanodots;

FIG. 5 shows the Grazing Incidence X-Ray Diffractometer pattern of nickel nanodots; and

FIG. 6 shows the vibrating sample magnetometer measurements of nickel nanodots measured under applied field either perpendicular or parallel to the sample surface.

### DETAILED DESCRIPTION OF THE INVENTION

The present invention relates to a method for fabricating metal nanodots comprising the steps: preparing a nanoporous polysulfone membrane; applying the nanoporous polysulfone membrane onto a substrate; depositing a metal into the pores of the polysulfone membrane thereby forming metal nanodots on the substrate; and removing the nanoporous polysulfone membrane.

The term “nanodots” herein is defined as nanoparticles of materials, especially those that are spherical, cubical or dodecahedral (solid hexagonal) in shape. The material of the nanodots may include metals, metal alloys, metal oxides, compounds containing metals, and combinations thereof.

The term “nanoporous membrane” refers to a membrane with pores that are in the nanometer range. Preferably, the pores have a diameter in a range of between about 0.1 nm to about 1000 nm.

The nanoporous polysulfone membranes of the invention can be formed by phase inversion process. Advantageously, these membranes so formed are known to possess uniform pore structure. The use of different pore formers and reduction in size of the pore former before the phase inversion allows one to adjust the pore diameter quite reliably. This along with the excellent heat and pH tolerant properties of polysulfone make nanoporous polysulfone membranes ideal matrices or templates for the synthesis of nanostructured materials. Growth of nanodots templated by polysulfone membrane may have a significant advantage that the size, shape and density of the nanodots can be easily controlled, by controlling the pore formation of the polysulfone membrane.

The nanoporous polysulfone membrane can be prepared by the steps of: adding a polysulfone into an organic solvent to provide a mixture; applying the mixture onto a substrate; and removing the solvent to provide a nanoporous polysulfone membrane. Preferably, the method further comprises a step of adding a pore former to the mixture.

In one embodiment, the polysulfone membrane of the present invention is prepared by the steps of (a) dissolving polysulfone pellets in an organic solvent by constant stirring, (b) adding a pore former and homogenously mixing with the solution of step (a) to obtain a membrane, (c) casting the said membrane onto a freshly cleaned substrate; and (d) immersing in deionized water to dissolve the pore former.

The organic solvent used for dissolving polysulfone may be any suitable solvent. Preferably, the organic solvent is selected from the group consisting of N-methylpyrrolidone, dimethylformamide, dimethylacetamide, chloroform, and combinations thereof. More preferably, the solvent is N-methylpyrrolidone or chloroform. Preferably, polysulfone pellets are dissolved in the organic solvent by continuous stirring at a constant temperature of about 45° C. for at least about 120 to about 200 minutes, preferably for about 180 minutes.

A pore former in the present invention is chosen such that altering the particle size of the pore former effectively controls the pore size of the membrane. The concentration of the pore former is preferably about 15 wt % of the polysulfone pellets used. In one embodiment of the invention, the pore former is polyvinylpyrrolidone. In a preferred embodiment of the invention, the pore former can be a highly volatile solvent such as chloroform, which can act as both the pore former and solvent when there is a requirement of fabricating membranes with very small pore sizes. The polysulfone membrane so obtained has a thickness of about 50 to about 500 nm, more preferably about 200 nm with a pore average diameter between about 80 and about 250 nm.

Preferably, the substrate used in the present invention comprises silicon or quartz. Quartz substrate is generally used in the case of memory storage applications, while silicon is particularly advantageous with respect to standard physical properties.

The metals of the present invention can be selected from the group consisting of Ni, Co, Fe, Mo, Pd, W, alloys thereof, oxides thereof, and combinations thereof. More preferred metals include Ni, Co and Fe due to their ferromagnetic nature, which can be used for bit-patterned media application, e.g., hard disks.

The deposition of metal may be performed using any physical vapor deposition technique. Some of them include sputtering, electron beam evaporation, electrodeposition, sonochemical deposition, molecular beam epitaxy and pulsed laser deposition. Even chemical vapor deposition techniques may be modified for deposition of the metal into the pores of the membrane of the present invention. However, electron beam evaporation and sputtering are more preferred over other techniques due to their low cost and high-throughput. The physical vapor deposition is typically performed under very high vacuum of about 5×10⁻⁷ mbar at the rate of about 0.1 Å/s.

The nanoporous polysulfone membrane can be removed by lifting off the polysulfone membrane, which results in individual islands of the metal being formed on the substrate. The sizes of the nanodots thus fabricated, can be easily tuned by varying the pore dimensions of the nanoporous polysulfone membrane. The metal nanodots so obtained have a diameter of about 25 to about 500 nm and height of about 2 to about 8 nm. More preferably, the diameter of the metal nanodots of the present invention is about 30 to about 180 nm.

The following examples illustrate certain embodiments and aspects of the present invention and not to be construed as limiting the scope thereof.

### Example 1

### Preparation of Polysulfone Membrane

The nanoporous polysulfone membrane was prepared by dissolving commercially available polysulfone pellets in N-methylpyrrolidone by continuous stirring at a constant temperature about 45° C. for about 180 minutes. 15 wt % of polyvinylpyrrolidone was homogenously mixed with this solution. A thin nanoporous membrane of thickness about 200 nm was then cast onto a freshly cleaned quartz substrate, after which it was immersed in deionized water to dissolve the pore former.

### Example 2

### Preparation of Nickel Nanodots

The fabricated membrane was applied onto the silicon substrate prior to electron beam evaporation. A thin film (about 10 nm) of nickel using an electron beam evaporation system was deposited under very high vacuum (about 5×10⁻⁷ mbar) at the rate of about 0.1\acute{Å}/s. After subsequent lift off of the polysulfone membrane, individual islands of nickel were formed on the silicon substrate.

### Example 3

### Characterization of Polysulfone Membrane and the Nickel Nanodots

Scanning electron microscopy was utilized to examine the periodicity and surface morphology of the nanoporous polysulfone membrane. The topography and morphology were studied using Agilent Technologies' atomic force microscope. All images were taken with silicon cantilevers with force constant about 0.02 to about 0.77 N/m, tip height of about 10 to 15 nm in contact mode. Magnetic force microscopy images were taken with cobalt coated silicon tip magnetized along the tip axis. The average lift height was maintained around 6 nm to effectively eliminate topographic interactions. The crystalline and phase purity were analyzed using Panalytical's X-ray diffractometer. The X-ray diffraction was carried out in grazing angle geometry, the incident beam fixed at ω=0.5° while scanning the detector. This incident angle was found to best attenuate diffraction from the substrate. The energy dispersive spectroscopy was taken to establish the presence of nickel and the vibrating sample magnetometer studies were conducted to ascertain the magnetic properties of the film of nickel nanodots.

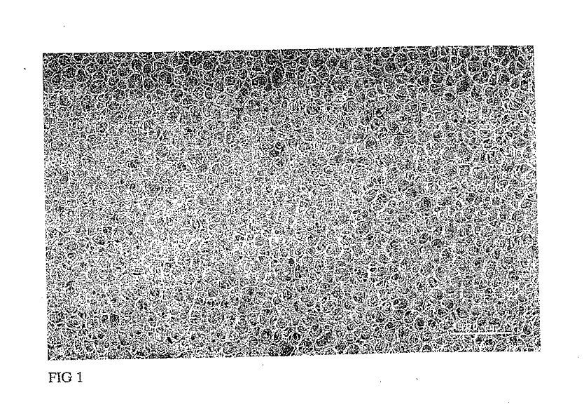

The surface morphology of the nanoporous polysulfone membrane fabricated using phase inversion polymerization is shown in FIG. 1. The entire surface is covered with densely packed pores in the polymer matrix. In the process of fabrication of the nanoporous membrane, the pores are formed due to the phase inversion of the pore former. The pore size can be controlled to a significant extent by reducing the particle size of the pore former before mixing it with the polysulfone solution. The average pore diameter is observed to be in a range of about 100 to about 200 nm. This is indicative of minor agglomeration of the pore former during the casting process. The pores are predominantly of elliptical nature with a few irregularities. The displaced pores of the layers below the top layer of the polysulfone membrane are clearly visible.

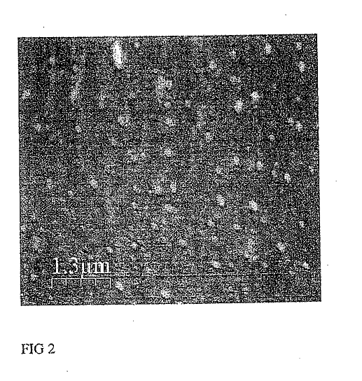

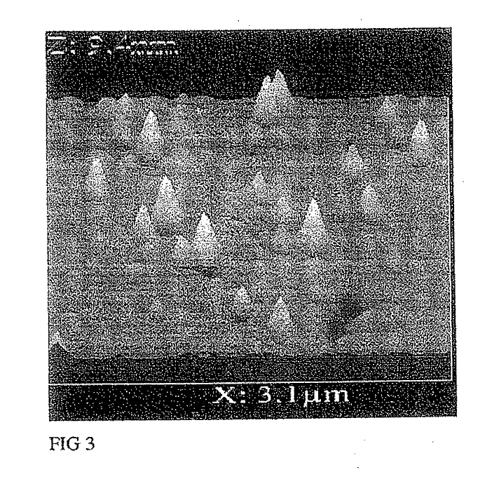

FIG. 2 shows atomic force microscopy images of the nickel nanodots. The image shows the growth of distinct two dimensional nickel nanodots. The nanodots are found to have diameters in the range of about 70 to about 120 nm and the height of about 3 to about 5 nm. The dimensions of the nanodots are slightly lesser as compared to the dimensions of the pores of the nanoporous membrane. Without wishing to be bound by theory, this is probably due to presence of the displaced pores in the subsequent layers of the nanoporous membrane causing the atoms of nickel to follow a slightly torturous path prior to deposition on the silicon substrate. The nickel nanodots also exhibit easily identifiable oblong shape anisotropy. FIG. 3 shows the three-dimensional image of the nickel nanodots. It shows that the nanodots are quite densely aligned around the substrate in correspondence the uniformity in the pore formation of the membrane. It is noticeable that the nanodots tend to have grown rather randomly as compared to the membrane. This is attributed to the thickness of the membrane and the presence of inter-displaced pores, which lead to the formation of preferential regions (nucleation sites) of growth. The presence of inter-displaced pores, results in convolution of the route (torturous path) to be followed by the nickel atoms to the silicon surface. Since all layers of the polysulfone membrane show similar pore formation and distribution, it can be expected that the final layer of the membrane (closest to the silicon substrate) has similar shape and size distribution. This predicts the formation of isolated nanodots growth for a 200 nm thick polysulfone membrane.

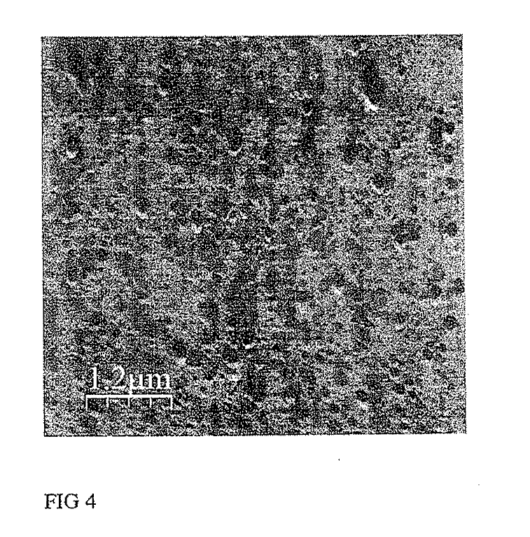

The magnetic force microscopy contrast images are shown in FIG. 4. The magnetic force microscopy images of nickel nanodots show good correspondence to the atomic force microscopy images. The nanodots can be clearly distinguished by the dark regions (attractive interactions). The formation of such distinct dark regions is indicative of uniform uniaxial magnetization of the nanodots and the presence of an easy axis of magnetization perpendicular to the sample.

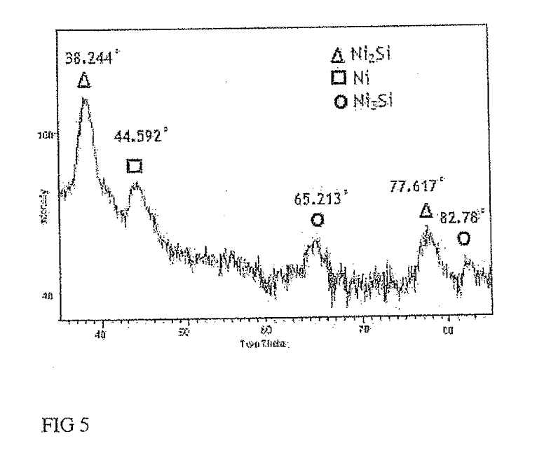

A grazing incidence X-ray diffractometer pattern of the nickel nanodots is shown in FIG. 5. Distinct peaks can be seen at 2θ=38.244°, 44.592° and 77.617° with varying intensities. The peak at 44.592° shows a good correspondence with the (111) phase of nickel (H. E. Swanson and E. Tatge, J. Res. Natl. Bur. Stand. (U.S.) 46, 318 (1951)). The sharp nature of the peak indicates a crystalline nature of the nickel nanodots. It can be noticed that there is a significant peak broadening of Ni (111). This can be attributed to the dimensions of the nanodots and the formation of textured polycrystalline material with variations in the (111) orientation (H. E. Swanson and E. Tatge, J. Res. Natl. Bur. Stand. (U.S.) 46, 318 (1951)).

The two secondary peaks at 2θ=38.244° and 77.617° are indicative of the (201) and (401) reflections of nickel silicide (Ni₂Si) (K. Toman, Acta Crystallogr. 5, 329 (1952)). The first Ni-rich phase Ni₂Si is known to form at the Ni—Si interface at ambient temperatures. This formation is usually understood to be a diffusion-controlled phenomenon. Also noticeable are peaks at 2θ=65.213° and 82.783° which are indicative of the (211) and (221) phases of Ni₃Si (N. F. Lashko, Dokl. Ak. Nauk. SSSR 81, 606 (1951); A. Osawa and M. Okamoto, J. Jpn. Inst. Met. 2, 378 (1938)). The formation of these nickel silicides is indicative of decrease in the number of the nickel atoms at the Ni—Si interface due to the presence of the nanoporous polysulfone membrane mask. The mask prevents the free diffusion of the nickel atoms and prevents the formation of the nickel rich NiSi phase usually formed at the Ni—Si interfaces at a temperature of 350°. This leads to absorption of Ni by the Ni₂Si nanostructures instead of the silicon substrate. It also prevents the formation of the NiSi₂ phase, which is the most thermodynamically favorable NiₓSi_{y} phase (E. A. Guliants and W. A. Anderson, J. Appl. Phys. 89, 4648 (2001); E. A. Guliants, C. Ji and W. A. Anderson, J. Appl. Phys. 91, 6078 (2002)).

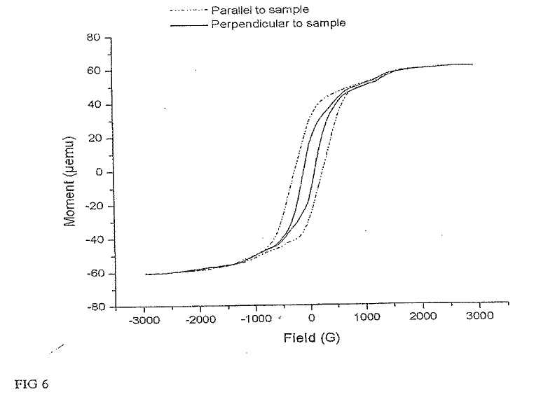

The hysteresis curves of the nickel nanodots grown on silicon substrate are shown in FIG. 6. The analysis of data was done after subtracting the substrate and holder offset as described by Diaz-Castanon et al. (S. Diaz-Castanon, J. C. Faloh-Gandarilla, E. Munoz-Sandoval and M. Terrones, Superlatt. Microstruct. 43, 482, (2008)). It is clear that the saturation field is greater when the applied field is perpendicular to the sample than when it is applied parallel to the sample. The coercivity is found to be 109 and 259 μemu when the field is applied perpendicular and parallel to the sample, respectively. This may be attributed to the tendency of nickel nanostructures to exhibit single domain nature, probably along the longer axis of the nanodots (C. G. Jin, W. F. Liu, C. Jia, X. Q. Xiang, W. L. Cai, L. Z. Yao and X. G. Lia, J. Crystal Growth 258, 337 (2003); M. Kroll, W. J. Blau, D. Grandjean and F. Luis, J. Magn. Magn. Mater. 249, 241 (2002); D. Routkevitch, T. Bibioni, M. Moskovits and M. Xu, J. Phys. Chem. 100, 14037 (2000); S. W. Lin, S. C. Chang, R. S. Liu, S. F. Hu and N. T. Jan, J. Magn. Magn. Mater. 282, 28 (2004)). This is found to be in good correspondence to the magnetic force microscopy contrast images (D. Routkevitch, T. Bibioni, M. Moskovits and M. Xu, J. Phys. Chem. 100, 14037 (2000)). The squareness (remanent magnetization/saturation magnetization) of the hysteresis curve is seen to be greater when the applied field is parallel to the sample as compared to when it is perpendicular to the sample surface; the squareness is 0.103 and 0.043, respectively. This, along with the low coercivity perpendicular to the surface is representative of the existence of an easy axis of magnetization perpendicular to the sample surface (M. Kroll, W. J. Blau, D. Grandjean and F. Luis, J. Magn. Magn. Mater. 249, 241 (2002)). It can be seen that the nickel nanodots exhibit excellent soft magnetic properties such as saturation magnetization, low coercivity, weak remanence magnetization and low squareness when the magnetizing field is perpendicular to the sample (Z. Huajun, Z. Jinhuan, G. Zhenghai and W. Wei, J. Magn. Magn. Mater. 320, 565 (2008)). This would make them ideal candidates for a number of devices based on magnetic materials.

The advantages of the present invention are shown in the following table.

| | | Size Range | | | |
|---|---|---|---|---|---|
| | Membrane | of | Cost | Fabrication | |
| | Employed | Nanodots | (INR) | Time | Remarks |
| Present | Polysulfone | 25-500 nm | Cheap | Few hours | Excellent for |
| Invention | | | 800,000 | | fabrication of |
| | | | | | magnetic nanodots. |
| | | | | | Controllability of |
| | | | | | particle size of |
| | | | | | nanodots achieved. |
| | | | | | Fabrication of |
| | | | | | spherical nanodots are |
| | | | | | possible. |
| Comparative | Polystyrene | 5-15 nm | Cheap | Few hours | The size range of |
| Example A | | | 800,000 | | the nanodots is |
| | | | | | severely restricted. |
| | | | | | This is a disadvantage |
| | | | | | as nanoparticles of |
| | | | | | most metals are not |
| | | | | | magnetic below 15 nm |
| | | | | | due to thermal |
| | | | | | fluctuation. |
| | | | | | Fabrication of |
| | | | | | spherical nanodots are |
| | | | | | not possible. |
| Comparative | Anodic | 100-600 nm | Cheap | 1-2 days for | Difficult to fabricate |
| Example B | Aluminium | | 800,000 | membrane | nanodots due to long |
| | Oxide | | | and few hours | channels. Usually |
| | | | | for nanodots | finds application in |
| | | | | | fabrication of |
| | | | | | nanowires and |
| | | | | | nanorods. |
| Comparative | No | 15-500 nm | Costly | Several days | Prohibitively |
| Example C | membrane | | 25,000,000 | | expensive. |
| Comparative | No | 15-100 nm | Costly | Several days | Prohibitively |
| Example D | membrane | | 10,000,000 | | expensive. |

Comparative Example A: S. L. Cheng et al., Journal of Physics and Chemistry of Solids 69 (2008) 620-624; Comparative Example B: C. G. Jin et al., Journal of Crystal Growth 258 (2003) 337-341; Comparative Example C: E. Leobanhung, et al., Appl. Phys. Lett. 67, 938 (1995); Comparative Example D: T. Yasuda, S. Yamasaki and S. Owo, Appl. Phys. Lett. 77, 3917 (2000).

Many modifications and other embodiments of the present disclosure will come to mind to one skilled in the art to which the present disclosure pertains having the benefit of the teachings presented in the foregoing description. It will be apparent to those skilled in the art that variations and modifications of the present disclosure can be made without departing from the scope or spirit of the present disclosure. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

1. A method for fabricating metal nanodots comprising the steps of:
preparing a nanoporous polysulfone membrane;
applying the nanoporous polysulfone membrane onto a substrate;
depositing a metal into the pores of the nanoporous polysulfone membrane thereby forming metal nanodots on the substrate; and
removing the nanoporous polysulfone membrane.

2. The method of claim 1, wherein the nanoporous polysulfone membrane has a thickness of about 50 to about 500 nm.

3. The method of claim 1, wherein the preparing of the nanoporous polysulfone membrane comprises the steps of:
adding a polysulfone into an organic solvent to provide a mixture;
applying the mixture onto a substrate; and
removing the solvent to provide a nanoporous polysulfone membrane.

4. The method of claim 3, wherein the organic solvent is selected from the group consisting of N-methylpyrrolidone, dimethylformamide, dimethylacetamide, chloroform, and combinations thereof.

5. The method of claim 3, further comprising a step of stirring the mixture for at least about 120 to about 200 minutes.

6. The method of claim 5, wherein the step of stirring the mixture is performed at a temperature of about 45° C.

7. The method of claim 3, furthering comprising a step of adding a pore former to the mixture.

8. The method of claim 7, wherein the pore former is polyvinylpyrrolidone or chloroform.

9. The method of claim 1, wherein the pores of the nanoporous polysulfone membrane have an average diameter of between about 80 and about 250 nm.

10. The method of claim 1, wherein the substrate comprises silicon or quartz.

11. The method of claim 1, wherein the metal is selected from the group consisting of Ni, Co, Fe, Mo, Pd, W, alloys thereof, oxides thereof, and combinations thereof.

12. The method of claim 11, wherein the metal is Ni.

13. The method of claim 1, wherein the metal is deposited by a method selected from the group consisting of sputtering, electron beam evaporation, electrodeposition, sonochemical deposition, molecular beam epitaxy, and pulsed laser deposition.

14. The method of claim 13, wherein the metal is deposited by electron beam evaporation.

15. The method of claim 14, wherein electron beam evaporation is performed under vacuum of about 5×10⁻⁷ mbar at a rate of about 0.1 Å/s.

16. The method of claim 1, wherein the metal nanodots have a diameter of about 30 to about 180 nm and height of about 2 to about 8 nm.

17. The method of claim 1, wherein the nanoporous polysulfone membrane is removed by lifting the membrane.

18. A system for preparing metal nanodots comprising:
a nanoporous polysulfone membrane;
a substrate; and
a metal.

19. A magnetic data storage medium comprising metal nanodots, wherein the metal nanodots are produced by the steps of:
preparing a nanoporous polysulfone membrane;
applying the nanoporous polysulfone membrane onto a substrate;
depositing a metal into the pores of the nanoporous polysulfone membrane thereby forming metal nanodots on the substrate; and
removing the nanoporous polysulfone membrane.

20. The magnetic data storage medium of claim 19, wherein the metal is selected from the group consisting of Ni, Co, Fe, and combinations thereof.
